(19) United States
(12) Patent Application Publication
(10) Pub. No.: US 2006/0291552 A1
(43) Pub. Date: Dec. 28, 2006

(54) Decision feedback equalizer

(76) Inventors: Evelina F. Yeung, San Jose, CA (US); Sanjay Dabral, Palo Alto, CA (US); James E. Jaussi, Hillsboro, OR (US); Alok Tripathi, Beaverton, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/159,522

(22) Filed: Jun. 22, 2005

(51) Int. Cl. H03H 7/30; H04B 1/10

(52) U.S. Cl. 375/233; 375/350

(57) ABSTRACT

In some embodiments, a circuit is provided that comprises a decision feedback equalizer to receive a bit stream signal. The equalizer comprises a summing circuit having a first input to receive a cursor bit sample from the bit stream, a second input to receive a first cursor bit signal, and an output to provide a cursor bit output signal corresponding to the cursor bit sample with at least some postcursor distortion removed therefrom. Other embodiments are disclosed and/or claimed herein.

### TECHNICAL FIELD

Embodiments disclosed herein relate generally to integrated circuit (“IC”) devices and in particular to receivers with decision feedback equalization.

### BACKGROUND

Point-to-point parallel links have shown potential in delivering high-bandwidth and low-latency inter-chip communication, and have been widely used in applications such as chip interconnections, networking and communication switches, memory interfaces, and multimedia product communications applications. With the design of such links, some design considerations may include bandwidth (increasing bit rate), latency (allowing for real-time data processing in the channels and improving phase noise tracking in clock-data recovery), cost/overhead, and I/O complexity (enabling the integration of a large number of I/Os in a system).

Frequency-dependent channel attenuation and signal distortion, which can lead to reduced received signal amplitude and inter-symbol interference (ISI), can make I/O design challenging. For example, a sampled bit in a bit stream can be distorted from precursor bits (precursor distortion) and/or postcursor bits (postcursor distortion). Precursor distortion results from energy in a bit sample that is effectively “projected” ahead by one or more upstream (or precursor) bits. Conversely, postcursor distortion is residual energy in a bit sample left from one or more downstream (or postcursor) bits. Fortunately, equalization may be used to address channel attenuation and compensate for either or both precursor and postcursor distortion.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a block diagram of a transceiver system with a receiver decision-feedback equalizer architecture.

FIG. 2 is a block diagram of a decision-feedback equalizer in a single data rate (SDR) clock data recovery (CDR) receiver in accordance with some embodiments of the present invention.

FIG. 3 is a timing diagram illustrating clock and data signals for some embodiments of the equalizer of FIG. 2.

FIG. 4 is a block diagram of a decision feedback equalizer in a double data rate (DDR) clock data recovery system with only data samplers in accordance with some embodiments of the present invention.

FIG. 5 is a timing diagram illustrating clock and data signals for some embodiments of the equalizers of FIG. 4.

FIG. 6 is a block diagram of a decision feedback equalizer in a double data rate (DDR) data recovery system with both data samplers and edge samplers in accordance with some embodiments of the present invention.

FIG. 7 is a timing diagram illustrating clock and data signals for some embodiments of the equalizers of FIG. 6.

FIG. 8 is a timing diagram illustrating the clock and data signals of FIG. 7 at different points in the equalizers of FIG. 6 for some embodiments.

FIG. 9 is a schematic diagram of a current summing circuit suitable for use in some embodiments of the equalizers of FIGS. 2, 4, and 6.

FIG. 10 is a schematic diagram of a regenerative latch suitable for use in some embodiments of the equalizers of FIGS. 2, 4, and 6.

FIG. 11 is a schematic diagram of a regenerative latch with a set-reset (S/R) latch suitable for use in some embodiments of the equalizers of FIGS. 2, 4, and 6.

FIG. 12 is a block diagram of a computer system with at least one decision feedback equalizer in accordance with some embodiments of the present invention.

### DETAILED DESCRIPTION

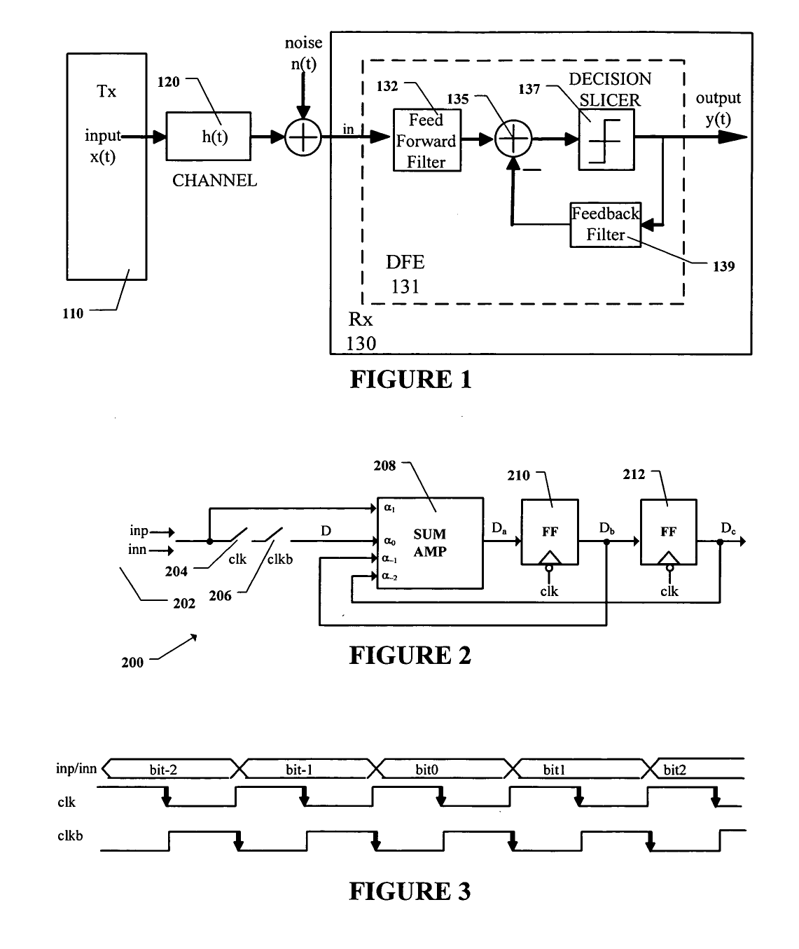

FIG. 1 shows a transceiver having a receiver with a decision feedback equalizer “DFE”) in accordance with some embodiments of the invention. The depicted transceiver comprises a transmitter 110, a receiver 130 including DFE 131, and a channel 120 communicatively linking the transmitter 110 to the receiver 130. The transceiver may be used to communicate digital information (e.g., in a bit stream signal) from the transmitter 110 to the receiver 130 over the channel 120. It could be used in any suitable components and/or applications including but not limited to point-to-point links between integrated circuit chips such as microprocessors, memory chips, and the like.

The terms “transmitter” and “receiver” are used in their ordinary sense and generally refer to devices for transmitting and receiving, respectively, bit stream signals over a channel. The term “channel” refers to a transmission path through which a signal (x(t) in the depicted figure) propagates from a transmitter output to a receiver input. It may include combinations of electrical, wireless, and/or optical transmission media. For example, it could include combinations of packaging components (e.g., bond wires, solder balls), package traces, sockets, printed-circuit board (PCB) traces, cables (e.g., coaxial, ribbon, twisted pair), wave guides, air (and any other wireless transmission media), optical cable (and other optical transmission components), and so on.

The DFE 131 may be used to reduce inter-symbol interference (ISI) so that data can effectively be recovered from a bit stream signal received from the transmitter 110. The depicted DFE comprises a feed-forward filter portion 132 to reduce precursor distortion and a feedback filter portion 139 to reduce postcursor distortion. It also includes a summer 135 and a decision slicer 137. The decision slicer 137 determines a digital value for a sampled bit based on the sum of weighted versions of the sampled bit, one or more previous bits (from feedback path 139) and/or one or more bits to follow (from feed-forward 132) summed together at summer 135. The basic idea is to skew the decision threshold of a received bit based on the values of previous bits (for postcursor distortion) and/or subsequent bits (for precursor distortion). Some embodiments may or may not include a feed-forward filter component 132 in the signal path from the input (“in”) to the summer 135. For example, a feed-forward filter might be omitted from a DFE when a filter is included in the transmitter to reduce precursor distortion from the transmitter side. In addition, the summed components may be positive or negative, i.e., they may be additive or subtractive, depending upon the characteristics of the channel. For example, weighted, e.g., reduced, versions of postcursor bit values may be subtracted from a bit sample to adjust for postcursor distortion. Moreover, there may be any number of summed components, depending on design considerations

With reference to FIGS. 2 and 3, a DFE 200 in a receiver for a single-data-rate (SDR) non-interleaved system, in accordance with some embodiments of the invention, is shown. It includes components for summing (or subtracting, depending on sign) previously assessed bit(s) (postcursor distortion) and bit samples of subsequent bit(s) (precursor distortion) in order to reduced their distorting effects on sampled bit data. In particular, the depicted equalizer comprises sample/hold (S/H) switches 204, 206, summing amplifier circuit 208, and first and second, falling edge-triggered flip-flops 210 and 212, all coupled to one another along a common pathway as indicated. The equalizer receives at its input a differential bit stream signal (inp/inn) and provides at its output digital data (D_{c}) recovered from the bit stream signal. (In the depicted embodiment, the signals are differential signals. Persons of skill, however, will recognize that the signals could also be implemented with single-ended signals.) At this point in the equalizer pathway, the bit stream signal (inp/inn) is suitably aligned with relevant receiver clock signals: clk, clkb (180 degrees out-of-phase with clk) by way of an upstream clock data recovery circuitry (not shown).

In the depicted embodiment, sample and hold (S/H) switches 204, 206 sample data on a clock's falling edge (as indicated in the timing diagram of FIG. 3). they may be implemented with any suitable circuit to capture (sample) and hold a value in response to a clock signal. Thus, as indicated in FIG. 3, S/H switch 204 samples bit data from the inp/inn bit stream signal. S/H switch 206 serves to hold the sampled bit for an additional half of a clock cycle so that it can properly be combined with the other inputs (i.e., previous and subsequent bit information) at summer 208.

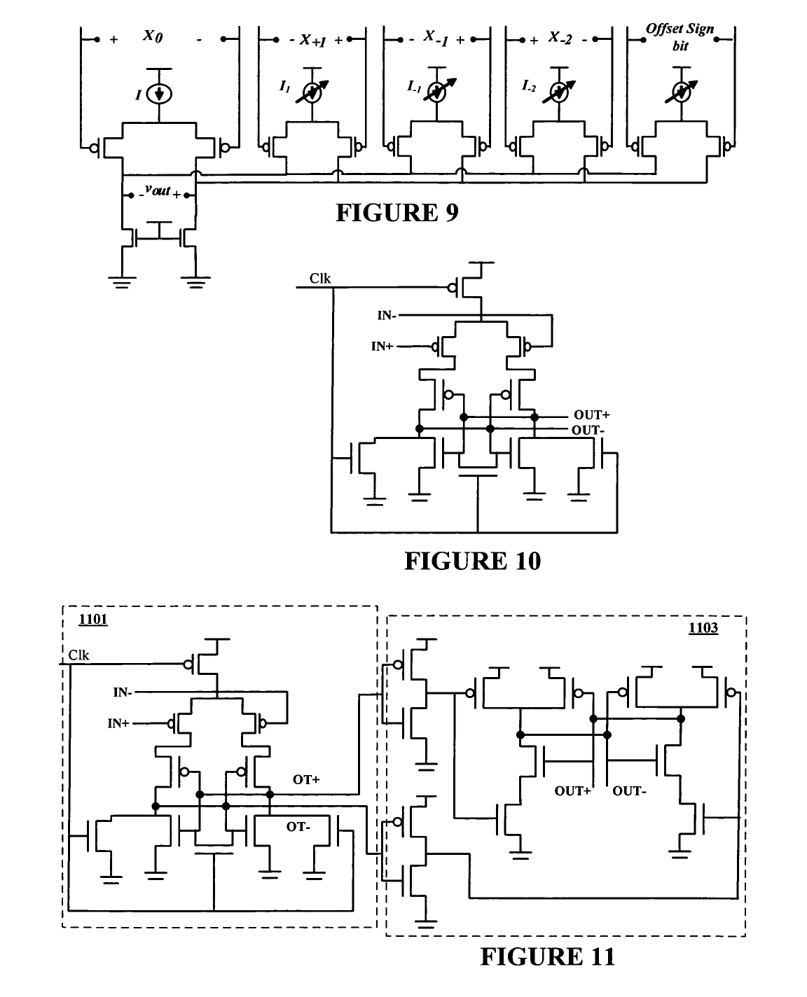

The summing circuit 208 may be implemented with any suitable circuit for summing together the inputs, as indicated, in a sufficient amount of time (e.g., to suitably make the resultant sum, Dₐ, available to flip-flop 210 within a given clock cycle). Its inputs and outputs may be voltage or current mode inputs/outputs, and any suitable summing approach (e.g., analog methodology) could be used. For example, an asynchronous and/or single-stage summing amplifier circuit such as the differential, current-mode digital-to-analog converter architecture, as shown in FIG. 9 (discussed below), could be used.

The depicted summing circuit 208 has four weighted inputs indicated at α₁, α₀, α₋₁, and α₋₂. Each “alpha” term corresponds to a coefficient value for multiplying (or weighting) its corresponding received input signal. The four inputs: α₁, α₀, α₋₁, and α₋₂ receive signals: inp/inn, D, D_{b}, and D_{c}, as indicated in FIG. 2. These signals correspond to four sequential (and typically adjacent) bits in the bit stream signal (inp/inn). D is a bit sample signal for a “present” (or cursor) bit; inp/inn is a signal value for a first precursor bit (the bit just behind the cursor bit); D_{b} is a bit signal for a first postcursor bit (the bit one bit ahead of the cursor bit); and D_{c} is a bit signal for the second postcursor bit (the bit two bits ahead of a cursor bit). It should be noted that the terms cursor (or present) bit, precursor bit, and postcursor bit are relative; that is, they correspond to bits of interest at a given node and at a given time. For example, with reference to FIG. 3, when the cursor bit is bit0, i.e., a bit sample of bit0 is at D, then the first precursor bit would correspond to bit1, the first postcursor bit would correspond to bit-1, and the second postcursor bit would correspond to bit-2. As the bit stream signal is clocked, the first precursor bit becomes the cursor bit, the cursor bit becomes the first postcursor bit, the first postcursor bit becomes the second postcursor bit, and so on. In addition, the bit signals for D and inp/inn are bit samples, e.g., sampled voltage or current signals from the bit stream signal; while D_{b} and D_{c} are bit signals resulting from previous summations at summer 208. Any of these bit signals may or may not yet be fully compliant digital signals, e.g., full complementary-metal-oxide-semiconductor “CMOS.”) The output, Dₐ, from the summing amplifier 208 can thus be expressed as:
D=α₋₂*D_{c}+α₋₁*D_{b}+α₀*D+α₁*(inp−inn)

By adding or removing precursor and/or postcursor energy from a sampled bit based on measured and/or determined values of its surrounding bit(s), the expected distorting effects attributable to precursor and/or postcursor energy can be reduced. Accordingly, the coefficient values, (α₁, α₀, α₋₁, α₋₂) may be selected based on measured or expected channel parameters so as to suitably reduce distortion resulting from such postcursor and/or precursor bits. The values may be positive or negative, and may vary depending upon desired performance and operating environments. In addition, they may be fixed or adjustable (e.g., through one time or multi-adjustable settings).

Moreover, while the depicted circuit uses four taps to process a first precursor, a cursor, a first postcursor, and a second postcursor, it should be appreciated that any number of taps to process a desired combination of precursors and/or postcursors could also be employed depending upon design considerations such as performance requirements and operating environment. For example, it has been observed that in some systems, the first postcursor bit (corresponding to D_{b}) may be the most problematic. Thus, in some equalizer embodiments, the α₋₂ term might be omitted. This may be especially appealing in systems requiring faster summing. Likewise, negligible distortion might arise from incoming precursors, and so the α₁ term could also (or alternatively) be omitted. Thus, with different systems and different needs, different combinations of feed-forward and feedback filters can be employed.

Flip-flops 210 and 212 may be implemented with any suitable circuitry in cooperation with the circuits used to implement S/H switches 204, 206 and summing amplifier 208 to receive, determine, store, and pass along bit values, e.g., in response to a clock signal. Such circuits could include but are not limited to switches, latches, flip flops, memory cells and the like. In addition, one or both may serve to “digitize” (or further digitize) its received bit value. That is, the output, Dₐ, at the summing amplifier 208 may not yet be fully digitized (e.g., converted to a suitable signal for a given logic type such as CMOS). Thus, either or both flip-flops 210 and 212 may act as decision slicers (or comparators) to appropriately digitize a received bit value. Along these lines, the depicted blocks could be implemented with any suitable combination of circuits and/or circuit components. For example, the summing amplifier could actually be implemented with one or several amplifiers, e.g., cascaded together. The same general principles apply to the other blocks.

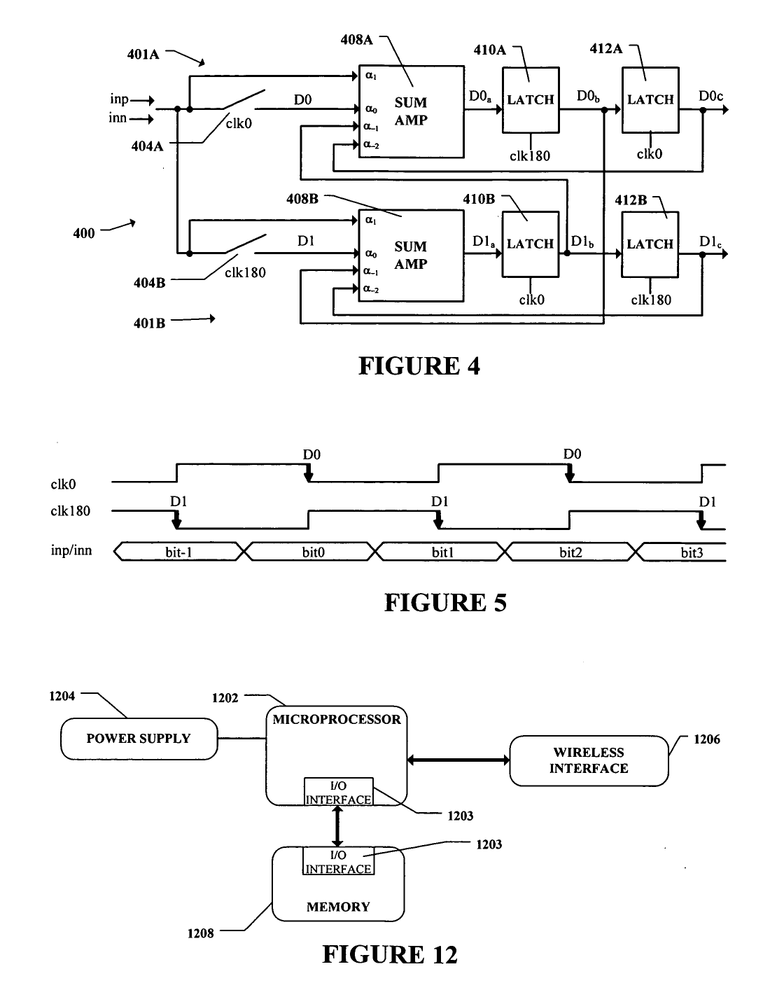

With reference to FIGS. 4 and 5, a DFE system 400 with first and second equalizer sections 401A and 401B is shown. This system is suitable for implementation in a two-way, interleaved double data rate (DDR) system. In some embodiments, the system 400 may be used with source-synchronous parallel links where receiver clock recovery is accomplished by sending a clock with the data from the transmitter. Thus, clock edge data recovery equalization may not be needed. As indicated in the timing diagram of FIG. 5, the equalizer sections (401A, 401B) are clocked with clock signals that are out of phase 180 degrees from one another. Equalizer section 401A recovers the odd bit data (bit-1, bit 1 . . . ), while equalizer section 401B recovers the even bit data.

The equalizer sections 401A and 401B may be implemented similarly to equalizer 200 from FIG. 2, except that the signals may be suitably coupled between the two equalizer sections as indicated. Note also that latches (410, 412) are shown instead of flip-flops. As used herein, the term “latch” is intended to cover any circuit suitable for use in an equalizer that can determine and store a bit value. It includes but is not limited to latches, flip-flops, registers, memory cells, and the like. In one embodiment, the first latches, 410, are implemented with regenerative latches, an example of which is shown in FIG. 10, and the second latches 412 are implemented with regenerative S/R latches, an example of which is shown in FIG. 11.

The evaluated first-summer cursor bit signal (taken at D0_{b}) from the 401A data path is fed into an input of the second summing circuit 408B as its first postcursor bit signal (the second-summer first postcursor bit signal). Likewise, the evaluated second-summer cursor bit signal (taken at D1_{b}) from the 401B data path is fed into an input of the first summing circuit 408A as its first postcursor bit signal (the first-summer first postcursor bit signal). This allows for the first postcursor energies to be reduced. (With some systems, DFE analysis shows that reducing the first postcursor energies may be responsible for half of the distortion reduction within a receiver, e.g., in terms of received signal margin improvement.) In each section, the second latch (412A/412B) holds the value for another half cycle and feeds it back to an additional input of its associated summing circuit as its second postcursor bit value thereby enabling the second postcursor energies to be cancelled.

If a preamplifier is utilized, a single preamplifier 402 can be used to amplify the received bit stream (IN) and provide the amplified signal to the separate equalizer paths (that is, separate pre-amps, if any, are not required.) In addition, with either equalizer section 401A/B, a single S/H switch 404 can be used to sample the bit stream (IN). This is so because the summing of the input signals at a summing amplifier (408A, 408B) occurs in a half-cycle before the resultant sum (D0ₐ, D1ₐ) is clocked through its first latch (410A, 410B). On the other hand, this implies that each summing amplifier should be capable of summing its signals and suitably providing its result within a relatively shorter time duration (i.e., within a half-cycle, as opposed to the full cycle allowed with the summing circuit of equalizer 200). Using a one-stage current summer (such as that shown in FIG. 9) reduces the delay and thus helps to meet timing requirements, which may be relatively tight such as with Gigabit implementations. Also, for example, in some CMOS processes, the transistors, whether PMOS or NMOS, may have channel modulation effects due to V_{ds} (drain-to-source voltage) variations, among other things. In addition, mirroring current can introduce matching errors. Hence, summing signals (e.g., currents) in a single stage helps to minimize such errors.

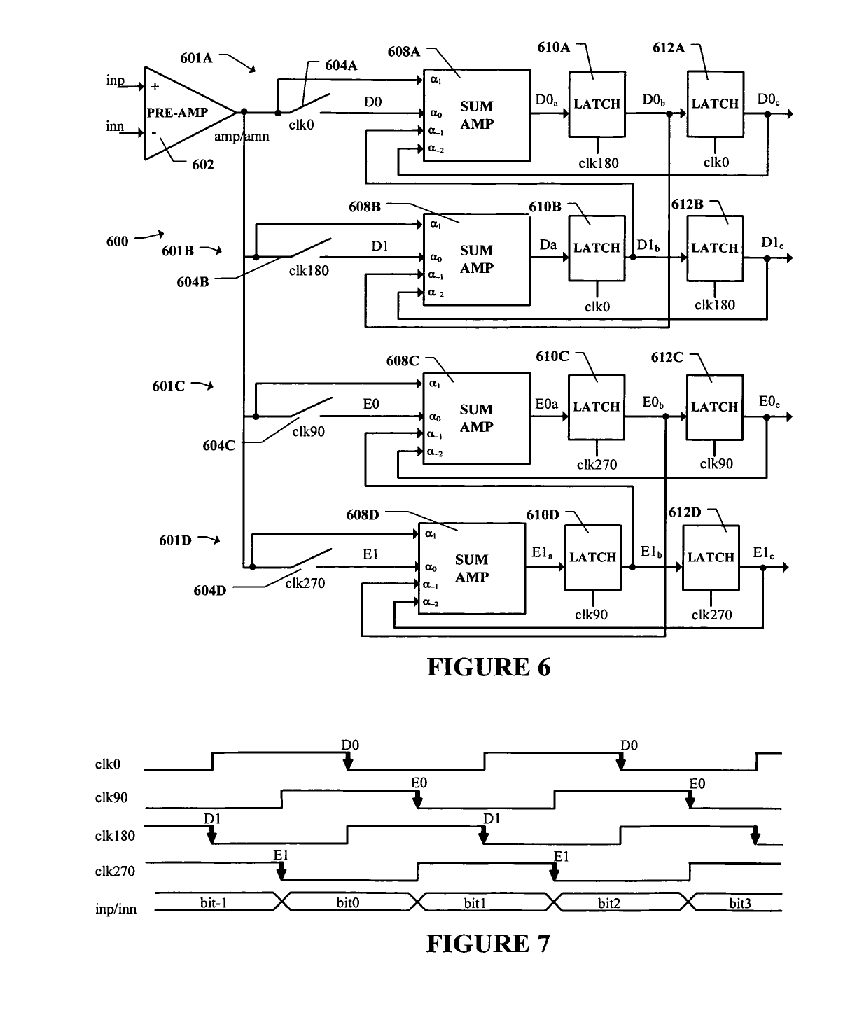

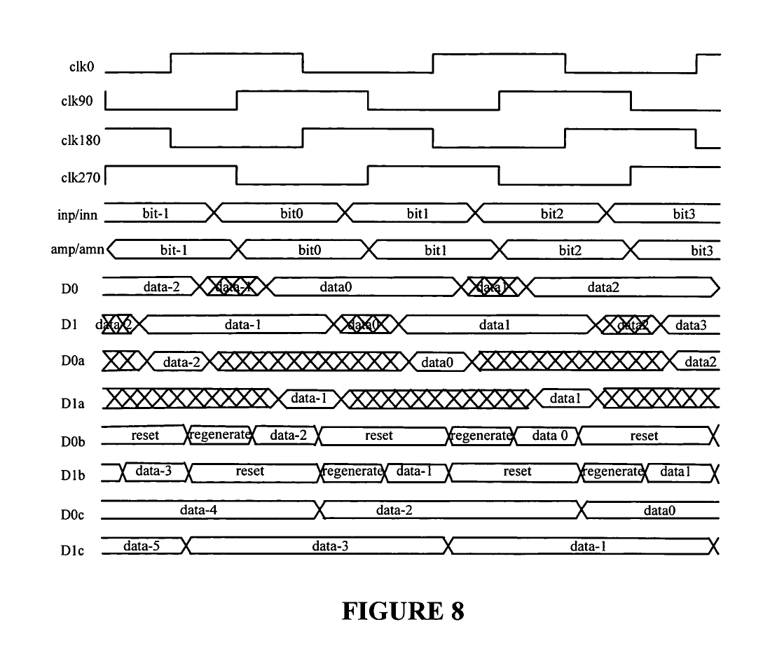

With reference to FIG. 6 through 8, equalizer system 600, suitable for use in a DDR data recovery scheme where dynamic phase error tracking is desired, is shown. With some serial links, the receiver may need to track dynamic phase errors in the data transition edges and thus, edge sample data may also be needed. With equalizer system 600, edge-recovery equalizer sections 601C, 601D are included (along with data equalizer sections 601A, 601B) for the recovery of such edge data from the input bit stream (inp/inn).

As indicated in FIGS. 6 and 7, data equalizer sections 601A, 601B are coupled together and operate similarly as the data equalizer sections 401A, 401B from FIG. 4. (In the depicted embodiment, however, a differential preamplifier circuit 602 is also included. It amplifies the incoming bit stream signal (inp/inn). In some embodiments, it is implemented with a suitably high bandwidth amplifier such as a high bandwidth differential amplifier.) Likewise, edge data equalizer sections 601C, 601D are coupled to one another and can operate the same as equalizer sections 601A, 601B, except that they are controlled with clocks (as indicated in FIG. 7) that are 90 degrees out of phase from corresponding clocks used with the data equalizer sections 601 A, 601B. They are used to capture the data bit edges from the data input stream (inp/inn).

(It should be appreciated that while single phase (SDR) and 2-phase (DDR) systems have been shown and discussed, any suitable multi-phase system (e.g., 4, 8, 16) could also be implemented consistent with the principles disclosed herein.)

FIG. 9 shows a simplified schematic of a suitable current summer for implementing a summing circuit. It may further have offset cancellation capability (not shown). As indicated in the figure, the offset compensation and equalizer taps are implemented using differential pairs with programmable (e.g., pre, post, or quasi-post manufacturing) current sources (i.e. the a coefficients as shown in FIGS. 2, 4, and 6). The tap coefficients may be selected for practical interconnect systems. Accordingly, the ranges of the coefficients may be limited to help reduce complexity, area, and power, as well as allowing higher performance (e.g., due to reduced parasitic loadings). The sign of each coefficient can be hard-coded (e.g., in the hardware) or made switchable.

In some embodiments, to avoid losing output signal swing at settings when not all the current legs are at their maximum values and have the same sign, the gate bias of the current sources (and hence the currents) may be automatically generated by an amplifier that monitors a half circuit replica (not shown). In this way, the output swing is adjustable, and can be set at maximal values regardless of what the equalizer settings are. In some embodiments, the output swing may be limited to ensure sufficient amplifier gain. The gain of the current summer stage can also be adjustable, which may be desirable since higher gain may be needed when a received input signal is small. In the depicted circuit, the current summer is implemented using PMOS differential pairs because the received input signals are referenced to Vₛₛ (the lower supply, or “Ground”) in an implemented signaling system. However, with some embodiments, an NMOS equivalent implementation may deliver equal or higher performance.

Because the current summer receives both digital (or digital like) and analog inputs, care may be taken to enhance the accuracy of an offset calibration procedure. For example, separate offset-trim-enable signals may be used for calibrating the offsets due to the differential pairs driven by analog inputs and those driven by digital inputs.

FIG. 10 shows a schematic of a possible implementation of a first-stage latch. FIG. 11 shows a schematic of a possible implementation of a second-stage latch. It should be noted that many variations of the implementations can also serve the same purposes.

With reference to FIG. 12, one example of a computer system is shown. The depicted system generally comprises a processor 1202 that is coupled to a power supply 1204, a wireless interface 1206, and memory 1208. It is coupled to the power supply 1204 to receive from it power when in operation. It is coupled to the wireless interface 1206 and to the memory 1208 with separate point-to-point links to communicate with the respective components. It, along with memory component 1208, includes an I/O interface 1203, which includes a receiver having at least one DFE equalizer according to some embodiments of the invention. For example, in some embodiments, the memory may be a DDR memory component, and the receivers in I/O interfaces 1203 may comprise equalizers in accordance with either the embodiments of FIG. 4 or 6. (Of course, other decision feedback equalizers in accordance with embodiments of the invention may be included in any of the depicted or non-depicted blocks including but not limited to communication links within chips or between chips.)

It should be noted that the depicted system could be implemented in different forms. That is, it could be implemented in a single chip module, a circuit board, or a chassis having multiple circuit boards. Similarly, it could constitute one or more complete computers or alternatively, it could constitute a component useful within a computing system.

The invention is not limited to the embodiments described, but can be practiced with modification and alteration within the spirit and scope of the appended claims. For example, it should be appreciated that the present invention is applicable for use with all types of semiconductor integrated circuit (“IC”) chips. Examples of these IC chips include but are not limited to processors, controllers, chip set components, programmable logic arrays (PLA), memory chips, network chips, and the like. Similarly, embodiments of the invention may be implemented in a variety of applications including but not limited to short-distance applications such as multiprocessor interconnections, networking and communication switches, memory interfaces, and consumer products with extensive multimedia applications.

Moreover, it should be appreciated that example sizes/models/values/ranges may have been given, although the present invention is not limited to the same. As manufacturing techniques (e.g., photolithography) mature over time, it is expected that devices of smaller size could be manufactured. In addition, well known power/ground connections to IC chips and other components may or may not be shown within the FIGS. for simplicity of illustration and discussion, and so as not to obscure the invention. Furthermore, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., circuits) are set forth in order to describe example embodiments of the invention, it should be apparent to one skilled in the art that the invention can be practiced without, or with variation of, these specific details. The description is thus to be regarded as illustrative instead of limiting.

What is claimed is:

1. A circuit, comprising:
a decision feedback equalizer to receive a bit stream signal, the equalizer comprising:
a summing circuit having a first input to receive a cursor bit sample, a second input to receive a first postcursor bit signal, and an output to provide a cursor bit signal corresponding to the cursor bit sample with at least some postcursor distortion removed therefrom.

2. The circuit of claim 1, in which the summing circuit is capable of summing weighted versions of the signals at the first and second inputs.

3. The circuit of claim 2, in which the summing circuit comprises a single-stage analog summing amplifier.

4. The circuit of claim 3, in which the summing circuit is a current-mode digital to analog converter circuit.

5. The circuit of claim 1, in which the equalizer comprises a second summing circuit having a first input to receive a cursor bit sample for the second summing circuit, a second input to receive a first postcursor bit signal for the second summing circuit, and an output to provide the first postcursor bit signal for the first-mentioned summing circuit corresponding to the cursor bit sample for the second summing circuit with at least some postcursor distortion removed therefrom.

6. The circuit of claim 5, in which the bit stream signal is a DDR bit stream signal, and the equalizer is to recover interleaved data therefrom.

7. The circuit of claim 5, in which the equalizer comprises:
(i) a first latch having an input coupled to the output of the first-mentioned summing circuit and an output coupled to the second input of the second summing circuit, and
(ii) a second latch having an input coupled to the output of the second summing circuit and an output coupled to the second input of the first-mentioned summing circuit, the first and second latches to be clocked with clock signals that are substantially 180 degrees out of phase from one another.

8. The circuit of claim 7, in which the first and second latches are regenerative latches.

9. The circuit of claim 8, in which the first-mentioned and second summing circuits are current-mode digital to analog converter circuits.

10. The circuit of claim 7, comprising a third latch having an input coupled to the first latch output and an output coupled to a third summing input of the first-mentioned summing circuit to provide it with a second postcursor bit signal for the first-mentioned summing circuit.

11. The circuit of claim 10, comprising a fourth latch having an input coupled to the second latch output and an output coupled to a third summing input of the second summing circuit to provide it with a second postcursor bit signal for the second summing circuit, the third and fourth latches to be clocked with clock signals that are substantially 180 degrees out of phase from one another.

12. The circuit of claim 11, in which the first-mentioned summing circuit, first latch, and third latch are part of a first equalizer section, the second summing circuit, second latch, and fourth latch are part of a second equalizer section, said first and second equalizer sections to recover interleaved bit data from the bit stream signal, and feedback paths within the first and second equalizer paths to the summing amps to have associated delay at least within one bit time.

13. The circuit of claim 12, comprising additional first and second equalizer sections to recover interleaved bit edge information from the bit stream signal.

14. A circuit, comprising:
an equalizer to receive a bit stream signal, the equalizer comprising:
(i) a first summing circuit having a first input to receive a first-summer cursor bit sample from the bit stream, a second input to receive a first-summer first postcursor bit signal, and an output to provide a first-summer cursor bit signal corresponding to the first-summer cursor bit sample with at least some postcursor distortion removed therefrom; and
(ii) a second summing circuit having a first input to receive a second-summer cursor bit sample, a second input to receive a second-summer first postcursor bit signal, and an output to provide a second-summer cursor bit signal corresponding to the second-summer cursor bit sample with at least some postcursor distortion removed therefrom, the second-summer cursor bit signal to be provided as the first-summer first postcursor bit signal.

15. The circuit of claim 14, in which the equalizer comprises:
(i) a first latch having an input coupled to the output of the first summing circuit and an output coupled to the second input of the second summing circuit, and
(ii) a second latch having an input coupled to the output of the second summing circuit and an output coupled to the second input of the first summing circuit, the first and second latches to be clocked with clock signals that are substantially 180 degrees out of phase from one another.

16. The circuit of claim 15, in which the first and second latches are regenerative latches.

17. The circuit of claim 16, in which the first and second summing circuits are current-mode digital to analog converter circuits.

18. The circuit of claim 15, comprising a third latch having an input coupled to the first latch output and an output coupled to a third summing input of the first summing circuit to provide it with a first-summer second postcursor bit signal.

19. The circuit of claim 18, comprising a fourth latch having an input coupled to the second latch output and an output coupled to a third summing input of the second summing circuit to provide it with a second-summer second postcursor bit signal, the third and fourth latches to be clocked with clock signals that are substantially 180 degrees out of phase from one another.

20. The circuit of claim 19, in which the first summing circuit, first latch, and third latch are part of a first equalizer section, the second summing circuit, second latch, and fourth latch are part of a second equalizer section, said first and second equalizer sections to recover interleaved bit data from the bit stream signal.

21. The circuit of claim 14, in which the first summing circuit comprises a fourth input to receive a first-summer first precursor bit sample for removing precursor distortion, and the second summing circuit comprises a fourth input to receive a second-summer first precursor bit sample for removing precursor distortion.

22. A system, comprising:
(a) a microprocessor having an I/O interface with an equalizer to receive a bit stream signal, the equalizer comprising:
(i) a first summing circuit having a first input to receive a first-summer cursor bit sample from the bit stream, a second input to receive a first-summer first postcursor bit signal, and an output to provide a first-summer cursor bit signal corresponding to the first-summer cursor bit sample with at least some postcursor distortion removed therefrom, and
(ii) a second summing circuit having a first input to receive a second-summer cursor bit sample, a second input to receive a second-summer first postcursor bit signal, and an output to provide a second-summer cursor bit signal corresponding to the second-summer cursor bit sample with at least some postcursor distortion removed therefrom, the second-summer cursor bit signal to be provided as the first-summer first postcursor bit signal; and
(b) a power supply coupled to the microprocessor to supply it with power.

23. The system of claim 22, in which the equalizer comprises:
(i) a first latch having an input coupled to the output of the first summing circuit and an output coupled to the second input of the second summing circuit, and
(ii) a second latch having an input coupled to the output of the second summing circuit and an output coupled to the second input of the first summing circuit, the first and second latches to be clocked with clock signals that are substantially 180 degrees out of phase from one another.

24. The system of claim 23, comprising a third latch having an input coupled to the first latch output and an output coupled to a third summing input of the first summing circuit to provide it with a first-summer second postcursor bit signal.

25. The system of claim 22, in which the power supply is a battery.
